(19) United States
(12) Patent Application Publication
(10) Pub. No.: US 2016/0062383 A1
(43) Pub. Date: Mar. 3, 2016

(54) POWER SUPPLY VOLTAGE DETECTOR CIRCUIT

(71) Applicant: KABUSHIKI KAISHA TOSHIBA, Tokyo (JP)

(72) Inventor: Hironori NAGASAWA, Yokohama Kanagawa (JP)

(21) Appl. No.: 14/634,425

(22) Filed: Feb. 27, 2015

(30) Foreign Application Priority Data
Aug. 26, 2014 (JP) 2014-171773

(51) Int. Cl. G05F 3/24; G01R 19/165

(52) U.S. Cl. CPC G05F 3/24; G01R 19/165

(57) ABSTRACT

A power supply voltage detector circuit includes a control signal terminal, switch circuit, first voltage detector circuit, and second voltage detector circuit. The first voltage detector circuit has a first input connected to a power supply terminal and a first output connected to the control signal input of the switch circuit. The first voltage detector circuit outputs a first-ON signal to a control signal input of the switch circuit when the power supply voltage is greater than or equal to the first threshold. The second voltage detector circuit has a second input connected to a power supply output of the switch circuit and second output connectable to a load circuit. The second voltage detector circuit outputs a second-ON signal to the control signal terminal to activate the load circuit when the voltage at the second input is greater than or equal to the second threshold.

### CROSS-REFERENCE TO RELATED APPLICATION

This application is based upon and claims the benefit of priority from Japanese Patent Application No. 2014-171773, filed Aug. 26, 2014, the entire contents of which are incorporated herein by reference.

### FIELD

Embodiments described herein relate generally to a power supply voltage detector circuit.

### BACKGROUND

In the related art, an integrated circuit in which multiple circuit blocks are integrated on a single chip is provided with a voltage detector circuit that detects a power supply voltage that is supplied from outside of the chip and is used to operate a load circuit. Generally, a voltage detector circuit detects whether the supplied power supply voltage is higher than or equal to a threshold voltage according to a difference between a first voltage obtained by dividing the power supply voltage using two resistors and a second voltage obtained by dividing the power supply voltage using a resistor and a diode. Furthermore, a voltage detector circuit generally activates a load circuit along with switching a power supply switch from being OFF (non-conducting state) to being ON (conducting state) only when the power supply voltage exceeds the threshold voltage.

In the voltage detector circuit described above, the divided voltage obtained by dividing the power supply voltage using a resistor and a diode has the problem of variations in diode operation caused by temperature changes (a characteristic of the diode—a temperature characteristic) varies with changing temperature. Additionally, divided voltage obtained by dividing the power supply voltage has a positive correlation with respect to the power supply voltage level. That is, the first and second voltages described above increase with increasing power supply voltage levels and decrease with decreasing power supply voltage levels. Thus, the above-described voltage detector circuit has issues with respect to stability of operation in response to variations in operating temperature and/or power supply voltage variations. Accordingly, the power supply voltage level that activates the load circuit is unstable and is affected by temperature changes and power supply fluctuations.

### DESCRIPTION OF THE DRAWINGS

FIG. 1 is a circuit diagram illustrating one example of the circuit configuration of a semiconductor integrated circuit that includes a power supply voltage detector circuit according to a first embodiment.

FIG. 2 is a circuit diagram illustrating one example of the circuit configuration of a first voltage detector circuit of the semiconductor integrated circuit illustrated in FIG. 1.

FIG. 3 is a waveform diagram illustrating example characteristics of a divided voltage and a first detected voltage with respect to a power supply voltage in the first voltage detector circuit illustrated in FIG. 2.

FIG. 4 is a circuit diagram illustrating one example of the circuit configuration of a second voltage detector circuit of the semiconductor integrated circuit illustrated in FIG. 1.

FIG. 5 is a circuit diagram illustrating one example of the circuit configuration of a bandgap reference circuit of the second voltage detector circuit illustrated in FIG. 4.

FIG. 6 is a waveform diagram illustrating examples of characteristics of a reference voltage and a second detected voltage at different temperatures with respect to the power supply voltage in the second voltage detector circuit that includes the bandgap reference circuit illustrated in FIG. 4 and FIG. 5.

FIG. 7 is a circuit diagram illustrating another example of the circuit configuration of the second voltage detector circuit of the semiconductor integrated circuit illustrated in FIG. 1.

### DETAILED DESCRIPTION

In an example embodiment, a power supply voltage detector circuit is provided that is less affected by temperatures even though including elements which have a characteristic temperature response.

In general, according to one embodiment, a power supply voltage detector circuit for operating a load circuit is provided. The power supply voltage detector circuit includes a power supply terminal, a ground terminal, and a control signal terminal. The power supply voltage detector circuit further includes a switch circuit having a power supply input, a power supply output, and a control signal input, where the power supply input is connected to the power supply terminal. The power supply voltage detector circuit further includes a first voltage detector circuit having a first input and a first output, where the first input is connected to the power supply terminal and the first output is connected to the control signal input of the switch circuit. The first voltage detector circuit is configured to: (1) send a first OFF signal to the control signal input of the switch circuit when the power supply voltage is lower than a first threshold, and (2) send a first ON signal to the control signal input of the switch circuit when the power supply voltage is higher than or equal to the first threshold. The power supply voltage detector circuit further includes a second voltage detector circuit having a second input and a second output, the second input connected to the power supply output of the switch circuit. The second voltage detector circuit is configured to: (1) output a second OFF signal from the second output to the control signal terminal to stop the load circuit when a voltage at the second input is lower than a second threshold which is higher than the first threshold, and (2) output a second ON signal from the second output to the control signal terminal to activate the load circuit when the voltage at the second input is higher than or equal to the second threshold.

Hereinafter, each embodiment will be described with reference to the accompanying drawings.

### First Embodiment

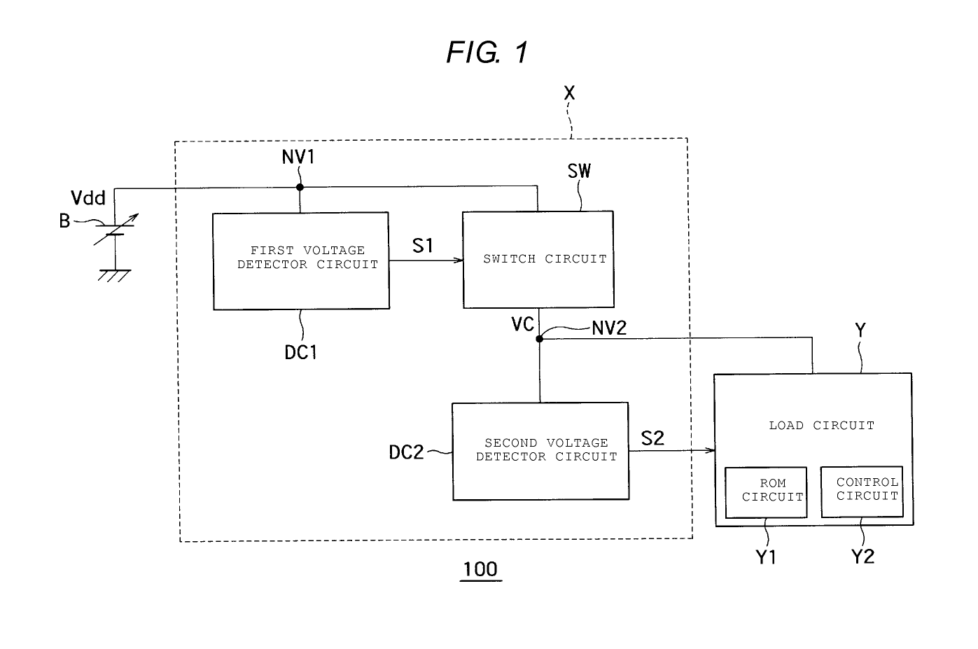

FIG. 1 is a circuit diagram illustrating one example of the circuit configuration of a semiconductor integrated circuit 100 that includes a power supply voltage detector circuit X according to a first embodiment.

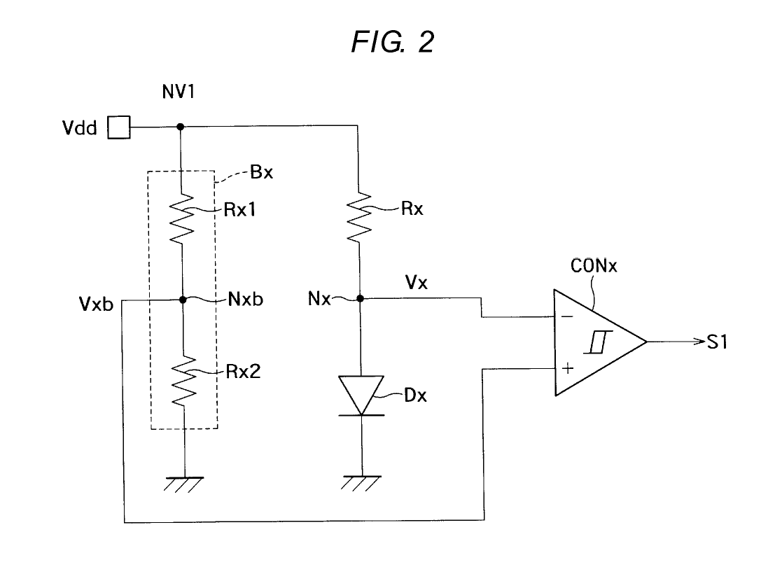

FIG. 2 is a circuit diagram illustrating one example of the circuit configuration of a first voltage detector circuit DC1 of the semiconductor integrated circuit 100 illustrated in FIG. 1.

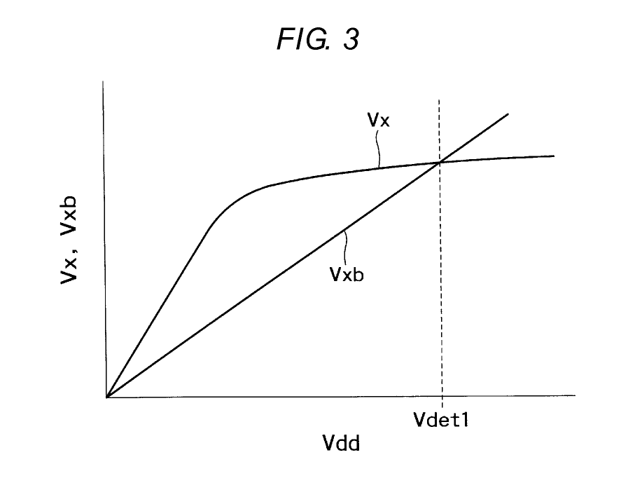

FIG. 3 is a waveform diagram illustrating one example of characteristics of a divided voltage Vxb and a first detected voltage Vx with respect to a power supply voltage Vdd in the first voltage detector circuit DC1 illustrated in FIG. 2.

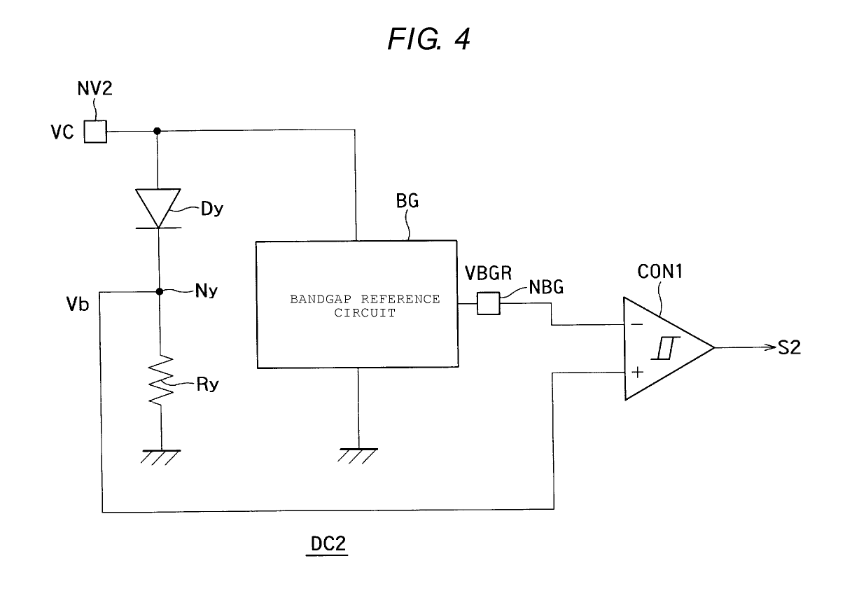

FIG. 4 is a circuit diagram illustrating one example of the circuit configuration of a second voltage detector circuit DC2 of the semiconductor integrated circuit 100 illustrated in FIG. 1.

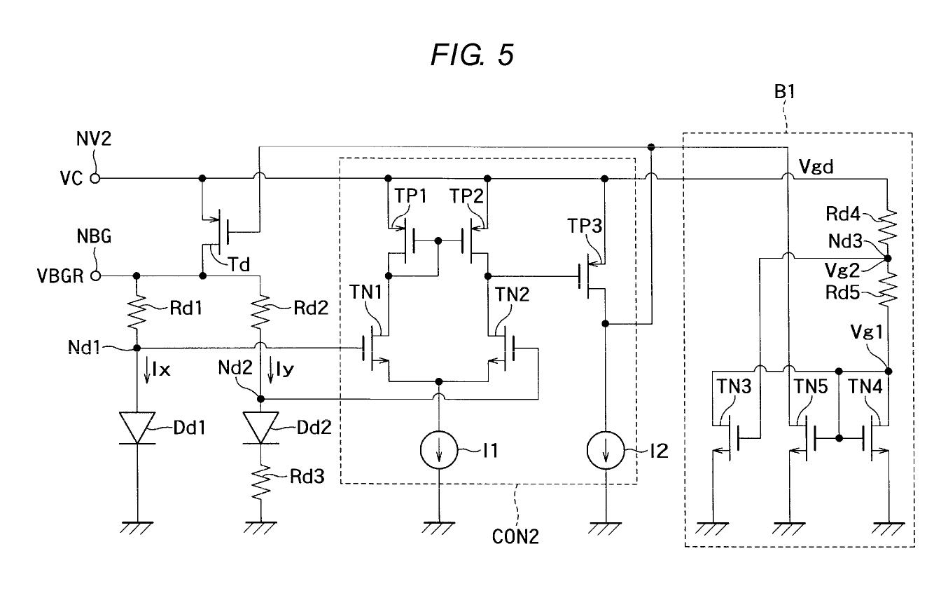

FIG. 5 is a circuit diagram illustrating one example of the circuit configuration of a bandgap reference circuit BG of the second voltage detector circuit DC2 illustrated in FIG. 4.

The semiconductor integrated circuit 100 includes the power supply voltage detector circuit X and a load circuit Y as illustrated in FIG. 1. A direct current power supply B is disposed outside the semiconductor integrated circuit 100.

The power supply voltage detector circuit X determines whether to supply a voltage (power supply voltage Vdd) that is supplied to a first power supply node NV1 by the direct current power supply B to the load circuit Y.

The load circuit Y operates by being supplied with the power supply voltage Vdd from the power supply voltage detector circuit X. The load circuit Y includes, for example, a read-only memory (ROM) circuit Y1 and a control circuit Y2 that controls a reading operation of the ROM circuit Y1. The load circuit Y may alternatively include a memory circuit, a logic circuit, or the like besides the ROM circuit shown.

The power supply voltage detector circuit X includes, for example, a switch circuit SW, the first voltage detector circuit DC1, and the second voltage detector circuit DC2 as illustrated in FIG. 1.

The switch circuit SW includes an input unit connected to the first power supply node NV1 and an output unit connected to a second power supply node NV2. That is, the switch circuit SW includes the input unit connected to the direct current power supply B and the output unit connected to the load circuit Y. The switch circuit SW is, for example, a MOS transistor (pMOS transistor) having one terminal (source) connected to the first power supply node NV1, the other terminal (drain) connected to the second power supply node NV2, and the gate voltage is controlled by a control signal 51 that the first voltage detector circuit DC1 outputs.

The switch circuit SW in an ON state conducts electricity between the first power supply node NV1 and the second power supply node NV2. Meanwhile, the switch circuit SW in an OFF state cuts off electricity between the first power supply node NV1 and the second power supply node NV2.

The first voltage detector circuit DC1 detects the power supply voltage Vdd at the first power supply node NV1. The first voltage detector circuit DC1 outputs control signal 51, based on the detected power supply voltage Vdd, to control the switch circuit SW.

The first voltage detector circuit DC1, for example, outputs the control signal S1 that causes the switch circuit SW to be OFF when the power supply voltage Vdd is lower than a first threshold Vdet1.

The first voltage detector circuit DC1 outputs control signal S1 to enable the switch circuit SW to be an ON state when the power supply voltage Vdd is higher than or equal to the first threshold Vdet1.

Referring to FIG. 2, the first voltage detector circuit DC1, for example, includes a first detection resistor Rx, a first detection diode Dx, a first voltage divider circuit Bx, and a comparator circuit CONx.

The first detection resistor Rx includes one terminal connected to the first power supply node NV1 and the other terminal connected to a first detection node Nx. The first detection resistor Rx, for example, is a polysilicon resistor.

The first detection diode Dx includes the anode connected to the first detection node Nx and the cathode is grounded. The first detection diode Dx, for example, is a PN junction diode or a Schottky barrier diode.

The first voltage divider circuit Bx outputs a divided voltage Vxb that is obtained by dividing the power supply voltage Vdd using a resistor Rx1 and a resistor Rx2 from a voltage divider node Nxb.

The comparator circuit CONx compares the divided voltage Vxb with the first detected voltage Vx of the first detection node Nx and outputs the control signal S1 to switch circuit SW based on the comparison result.

As illustrated in FIG. 3, the divided voltage Vxb is set to be lower than the first detected voltage Vx when the power supply voltage Vdd is lower than the first threshold Vdet1. The divided voltage Vxb is set to be higher than or equal to the first detected voltage Vx when the power supply voltage Vdd is higher than or equal to the first threshold Vdet1.

The comparator circuit CONx outputs the control signal S1 that enables the switch circuit SW to be turned OFF when the divided voltage Vxb is lower than the first detected voltage Vx (i.e., when the power supply voltage Vdd is lower than the first threshold Vdet1).

The comparator circuit CONx outputs the control signal S1 that allows the switch circuit SW to be turned ON when the divided voltage Vxb is higher than or equal to the first detected voltage Vx (i.e., when the power supply voltage Vdd is higher than or equal to the first threshold Vdet1).

The second voltage detector circuit DC2 illustrated in FIG. 1 is operated by a voltage VC, which is the power supply voltage Vdd passed through the switch circuit SW when the switch circuit SW is turned ON.

The second voltage detector circuit DC2 detects the voltage VC at the second power supply node NV2 (output unit of the switch circuit SW). The second voltage detector circuit DC2 outputs a control signal S2 to control the activation (operation) of the load circuit Y based on the detected voltage VC and a second threshold Vdet2.

The second voltage detector circuit DC2, for example, outputs the control signal S2 so as to prevent the activation of the load circuit Y when the voltage VC at the second power supply node NV2 is lower than the second threshold Vdet2 for cases where Vdet2>Vdet1.

The second voltage detector circuit DC2 outputs the control signal S2 so as to activate (enable) the load circuit Y (permit the activation of the load circuit Y) when the voltage VC at the second power supply node NV2 is higher than or equal to the second threshold Vdet2.

The second voltage detector circuit DC2, for example, includes a second detection diode Dy, a second detection resistor Ry, the bandgap reference circuit (reference voltage circuit) BG, and a first comparator circuit CON1 as illustrated in FIG. 4.

The bandgap reference circuit BG is activated when the voltage VC at the second power supply node NV2 is supplied through the switch circuit SW. The bandgap reference circuit BG outputs a reference voltage VBGR to a reference node NBG.

Referring to FIG. 1, the ON resistance of the switch circuit SW is low so that the voltage VC at the second power supply node NV2 substantially equals the power supply voltage Vdd when the switch circuit SW is in a state of ON (that is, when the power supply voltage Vdd is higher than or equal to the first threshold Vdet1).

The second detection diode Dy includes the anode connected to the second power supply node NV2 and the cathode connected to the second detection node Ny. The second detection diode Dy, for example, is a PN junction diode or a Schottky barrier diode.

The second detection resistor Ry includes one terminal connected to the second detection node Ny and the other terminal connected to a ground. The second detection resistor Ry, for example, is a polysilicon resistor.

The first comparator circuit CON1 compares the reference voltage VBGR with a second detected voltage Vb at the second detection node Ny and outputs the control signal S2 that controls the activation of the load circuit Y based on the comparison result.

The first comparator circuit CON1, for example, outputs the control signal S2 so as to prevent the activation of the load circuit Y when the second detected voltage Vb is lower than the reference voltage VBGR.

The first comparator circuit CON1 outputs the control signal S2 to activate (enable) the load circuit Y (permit the activation of the load circuit Y) when the second detected voltage Vb is higher than or equal to the reference voltage VBGR.

The bandgap reference circuit BG described above, for example, includes a driving MOS transistor Td, a first diode Dd1, a second diode Dd2, a first resistor Rd1, a second resistor Rd2, a third resistor Rd3, and a second comparator circuit CON2 as illustrated in FIG. 5.

The driving MOS transistor Td includes one terminal (source) connected to the second power supply node NV2 and the other terminal (drain) connected to the reference node NBG. The driving MOS transistor Td here is a pMOS transistor.

The first resistor Rd1 includes one terminal connected to the reference node NBG and the other terminal connected to a first node Nd1.

The first diode Dd1 includes the anode connected to the first node Nd1 and the cathode connected to ground.

The second resistor Rd2 includes one terminal connected to the reference node NBG and the other terminal connected to a second node Nd2.

The resistance of the first resistor Rd1, for example, can be equal the resistance value of the second resistor Rd2.

The second diode Dd2 includes the anode connected to the second node Nd2.

The third resistor Rd3 includes one terminal connected to the cathode of the second diode Dd2 and the other terminal connected to ground.

The second comparator circuit CON2 controls the gate voltage of the driving MOS transistor Td so that a first divided voltage at the first node Nd1 equals a second divided voltage at the second node Nd2 (that is, CON2 adjusts the gate voltage applied to the driving MOS transistor Td such that the first node Nd1 and the second node Nd2 will be at the same potential).

The second comparator circuit CON2, for example, includes a first pMOS transistor TP1, a second pMOS transistor TP2, a third pMOS transistor TP3, a first nMOS transistor TN1, a second nMOS transistor TN2, a first current source I1, and a second current source 12 as illustrated in FIG. 5.

The first pMOS transistor TP1 includes one terminal (source) connected to the second power supply node NV2 and is diode-connected.

The first nMOS transistor TN1 includes one terminal (drain) connected to the other terminal (drain) of the first pMOS transistor TP1 and the gate of the first nMOS transistor is connected to the first node Nd1.

The first current source I1 is connected between the other terminal (source) of the first nMOS transistor TN1 and ground. The first current source I1 outputs a predetermined current.

The second pMOS transistor TP2 includes one terminal (source) connected to the second power supply node NV2 and a gate connected to the gate of the first pMOS transistor TP1.

The second nMOS transistor TN2 includes one terminal (drain) connected to the other terminal (drain) of the second pMOS transistor TP2, and the other terminal (source) connected to the other terminal (source) of the first nMOS transistor TN1, and the gate connected to the second node Nd2.

The third pMOS transistor TP3 includes one terminal (source) connected to the second power supply node NV2 and the other terminal (drain) connected to the gate of the driving MOS transistor Td.

The second current source 12 is connected between the other terminal (drain) of the third pMOS transistor TP3 and ground. The second current source 12 outputs a predetermined current.

A starter circuit B1 controls the gate voltage of the driving MOS transistor Td so that the driving MOS transistor Td is turned ON while the power supply voltage Vdd is lower than the second threshold Vdet2.

The starter circuit B1, for example, includes a fourth resistor Rd4, a fifth resistor Rd5, a third nMOS transistor TN3, a fourth nMOS transistor TN4, and a fifth nMOS transistor TN5 as illustrated in FIG. 5.

The fourth resistor Rd4 includes one terminal connected to the second power supply node NV2 and the other terminal connected to a third node Nd3.

The fifth resistor Rd5 includes one terminal connected to the third node Nd3.

The third nMOS transistor TN3 includes one terminal (drain) connected to the other terminal of the fifth resistor Rd5, the other terminal (source) connected to ground, and the gate of the third nMOS transistor TN3 is connected to the third node Nd3.

The fourth nMOS transistor TN4 includes one terminal (drain) connected to the other terminal of the fifth resistor Rd5 and the other terminal (source) connected to ground and is diode-connected.

The fifth nMOS transistor TN5 includes one terminal (drain) connected to the gate of the driving MOS transistor Td, the other terminal (source) connected to a ground, and the gate of the fifth nMOS transistor TN5 is connected to the gate of the fourth nMOS transistor TN4.

The first and the second diodes Dd1 and Dd2 are, for example, PN junction diodes.

The first to the fifth resistors Rd1 to Rd5 are, for example, polysilicon resistors.

One example of the operation of the bandgap reference circuit BG is illustrated in FIG. 5 and will be described next.

Hereinafter, Vthn is a threshold voltage of the third to the fifth nMOS transistors TN3 to TN5, Vthp is a threshold voltage of the driving MOS transistor (pMOS transistor) Td, and Ron3, Ron4, and Ron5, respectively, are the ON resistances of the third to the fifth nMOS transistors TN3 to TN5. In this context, “ON resistance” means an electrical resistance to conductance between source and drain when a transistor is in a conductive state (ON state).

In the bandgap reference circuit BG, for example, currents Ix and Iy flow through the first and the second resistors Rd1 and Rd2 once the driving MOS transistor Td is first ON. Accordingly, the operating point of the second comparator circuit CON2 is determined, a feedback loop is formed, and the second comparator circuit CON2 continues to be operated. To continue the operation of the second comparator circuit CON2, the voltage VC must be higher than or equal to the ON voltage of the first and the second diodes Dd1 and Dd2.

Next, the operation of the starter circuit B1 that allows the driving MOS transistor Td to be turned ON when the power supply voltage Vdd rises up to or over the first threshold Vdet1 will be described.

Referring to FIG. 1, the voltage VC at the second power supply node NV2 rises when the power supply voltage Vdd rises up to or over the first threshold Vdet1 from 0 V, and the switch circuit SW is turned ON.

Referring to FIG. 5, all of the third to the fifth nMOS transistors TN3 to TN5 are in the state of OFF when the voltage VC is lower than the threshold voltage Vthn.

Accordingly, the gate voltage Vg2 of the third nMOS transistor TN3 and the gate voltage Vg1 of the fourth and the fifth nMOS transistors TN4 and TN5 equal the voltage VC. This results in the gate voltage Vgd of the driving MOS transistor Td is close to being in an unstable state because the drain of the fifth nMOS transistor TN5 is in a high impedance state due to the gate voltage only being equal to and not above the threshold voltage.

Thereafter, when the voltage VC at the second power supply node NV2 exceeds the threshold voltage Vthn, the gate voltages Vg1 and Vg2 also exceed the threshold voltage Vthn and, each of the third to the fifth nMOS transistors TN3 to TN5 turn ON.

The fifth nMOS transistor TN5 being turned ON causes the gate voltage Vgd of the driving MOS transistor Td to start to drop.

The driving MOS transistor Td is turned ON when the value obtained by subtracting the gate voltage Vgd from the voltage VC exceeds the absolute value of the threshold voltage Vthp of the driving MOS transistor Td.

Then, the second comparator circuit CON2 is activated when the driving MOS transistor Td is turned ON as described above.

The third and the fourth nMOS transistors TN3 and TN4 being turned ON allows current to flow through the fourth and the fifth resistors Rd4 and Rd5. Accordingly, a voltage drop occurs because of the fourth and the fifth resistors Rd4 and Rd5, as illustrated in Expressions 1 and 2. In Expressions and 2, “Ron3//Ron4” denotes the combined, effective resistance of the ON resistances of the parallel-connected third and the fourth nMOS transistors TN3 and TN4.

Vg1=VC×(“Ron3//Ron4”)/(Rd4+Rd5+“Ron3//Ron4”) (Expression 1)

Vg2=VC×(Rd5+“Ron3//Ron4”)/(Rd4+Rd5+“Ron3//Ron4”) (Expression 2)

Here, it is assumed that Rd4>>“Ron3//Ron4”, and Rd5>>“Ron3//Ron4”. Accordingly, the following approximation may be made: Vg1≅0 V (ground voltage), and Vg2≅VC×Rd5/(Rd4+Rd5) when the third and the fourth nMOS transistors TN3 and TN4 are turned ON.

When the voltage Vg1 drops to around ground voltage, the fourth and the fifth nMOS transistors TN4 and TN5 turn OFF since Vg1≅0 V<Vthn. The fifth nMOS transistor TN5 being turned OFF allows the driving MOS transistor Td to maintain the ON state. Therefore, the second comparator circuit CON2 may continue to operate without operation of the starter circuit B1.

The third nMOS transistor TN3 can be maintained in the ON state by having the ratio of the fourth resistor Rd4 and the fifth resistor Rd5 be set so that Vg2>Vthn. Accordingly, electrical potentials of the gate voltages Vg1 and Vg2 are consistently maintained, and the fourth and the fifth nMOS transistors TN4 and TN5 maintain the OFF state thereof.

According to the above description, the reference voltage VBGR may be output in a stable manner since the starter circuit B1 allows the driving MOS transistor Td to be securely turned ON, and the bandgap reference circuit BG activated when the power supply voltage Vdd rises up to or over the first threshold Vdet1.

In addition, the temperature characteristic of the forward voltages of two PN junction diodes (the first and the second diodes Dd1 and Dd2), may differ from each other because the junction areas of the two PN junction diodes may differ from each other. Thus, the temperature characteristics of the forward voltages of these PN junction diodes may be provided to offset each other in the bandgap reference circuit BG. Accordingly, the reference voltage VBGR may be consistently output even when operating temperatures vary. In addition, the reference voltage VBGR is also stable with respect to the power supply voltage Vdd, provided that the power supply voltage Vdd is higher than or equal to a certain voltage level. A “certain voltage level” may shift somewhat depending on the specific elements included in an actual bandgap reference circuit BG.

Next, one example of the operation of the power supply voltage detector circuit X that has the above configuration will be described.

As described above, the first voltage detector circuit DC1 allows the switch circuit SW to be turned ON when the power supply voltage Vdd rises up to the first threshold Vdet1 from 0 V.

Accordingly, the power supply voltage Vdd is transferred to the power supply line (second power supply node NV2) of the second voltage detector circuit DC2, and the second voltage detector circuit DC2 starts to be operated.

Thereafter, the second voltage detector circuit DC2 permits the activation of the load circuit Y when the voltage VC (power supply voltage Vdd) is greater than or equal to the second threshold Vdet2.

Accordingly, supplied with a voltage VC that is higher than or equal to the second threshold Vdet2, the load circuit Y is activated (enabled) and is capable of being normally operated.

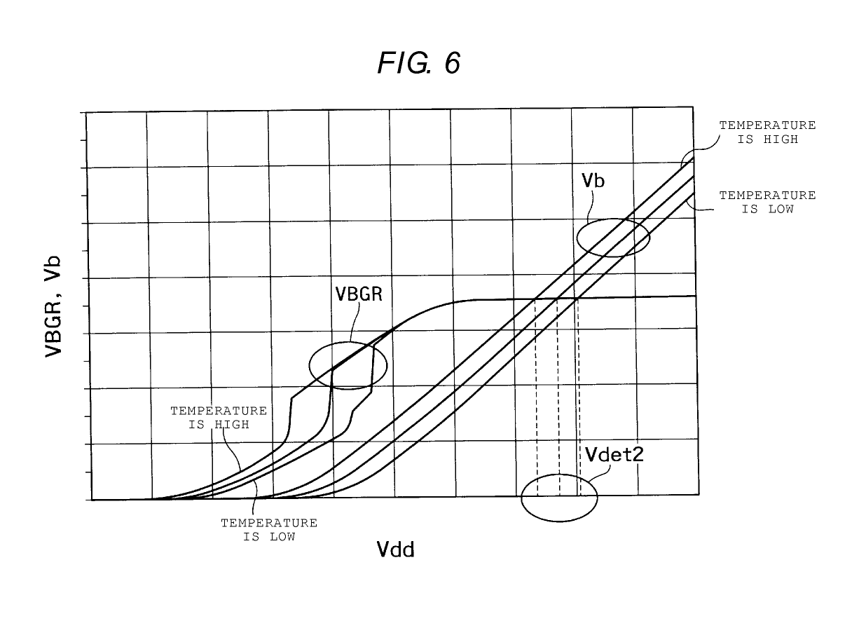

FIG. 6 is a waveform diagram illustrating one example of characteristics of the reference voltage VBGR and the second detected voltage Vb with respect to the power supply voltage Vdd in the second voltage detector circuit DC2 that includes the bandgap reference circuit BG illustrated in FIG. 4. FIG. 6 illustrates a circuit simulation result when the power supply voltage Vdd is directly supplied to the second power supply node NV2 of the second voltage detector circuit DC2.

As illustrated in FIG. 6, the reference voltage VBGR and the second detected voltage Vb intersects only at one point (the second threshold Vdet2) when the power supply voltage Vdd rises. The voltage at which the power supply voltage Vdd equals the second threshold Vdet2 may be detected by comparing the reference voltage VBGR with the second detected voltage Vb.

Furthermore, the deviation of the second threshold Vdet2 is mainly determined by the accuracy of the second detected voltage Vb since the reference voltage VBGR is not significantly dependent on changes to the power supply voltage Vdd or temperature over the relevant range of power supply voltage Vdd

Accordingly, the deviation of the second threshold Vdet2 is primarily determined by the temperature deviation of the ON voltage of a PN junction diode (the second detection diode Dy) and the temperature deviation of the resistor Ry (change in resistance value for resistor Ry due to change in temperature). However, the temperature deviation of Dy and the temperature deviation of the resistor Ry can be negated by selecting a material that causes the temperature coefficient of a resistor to be negative since the temperature coefficient of a PN junction diode is negative. Consequently, the temperature deviation of the second detected voltage Vb detected at the second detection node Ny is decreased. Therefore, the second voltage detector circuit DC2 may accurately detect voltages.

As discussed above in reference to FIG. 5, the reference voltage VBGR remains around 0 V while the power supply voltage Vdd is between 0 V (ground voltage) and the ON voltage of a PN junction diode in the bandgap reference circuit BG.

For this reason, in the first embodiment, the first voltage detector circuit DC1 monitors the power supply voltage Vdd while the power supply voltage Vdd is between 0 V and the first threshold Vdet1. The second voltage detector circuit DC2 monitors the power supply voltage Vdd (voltage VC) when the power supply voltage Vdd is higher than or equal to the first threshold Vdet1.

The second voltage detector circuit DC2 is operated only when the switch circuit SW is in the state of ON. Accordingly, the second voltage detector circuit DC2 does not consume power when the power supply voltage Vdd is lower than the first threshold Vdet1.

The bandgap reference circuit BG is activated when the power supply voltage Vdd is higher than or equal to any higher one of the ON voltage of the PN junction diodes and the threshold voltage Vthn. Accordingly, the difference between the reference voltage VBGR and the second detected voltage Vb may be obtained (e.g., see FIG. 6), and the noise tolerance of the power supply voltage Vdd becomes excellent when the power supply voltage Vdd is lower than the second threshold voltage Vdet2 and is higher than or equal to the voltage that activates the bandgap reference circuit BG.

In other words, the power supply voltage detector circuit according to the first embodiment may be less affected by temperature changes even though it includes elements that have a characteristic (e.g., resistivity or threshold conductance) that varies with temperature, which may be referred to as a “temperature characteristic.”

### Second Embodiment

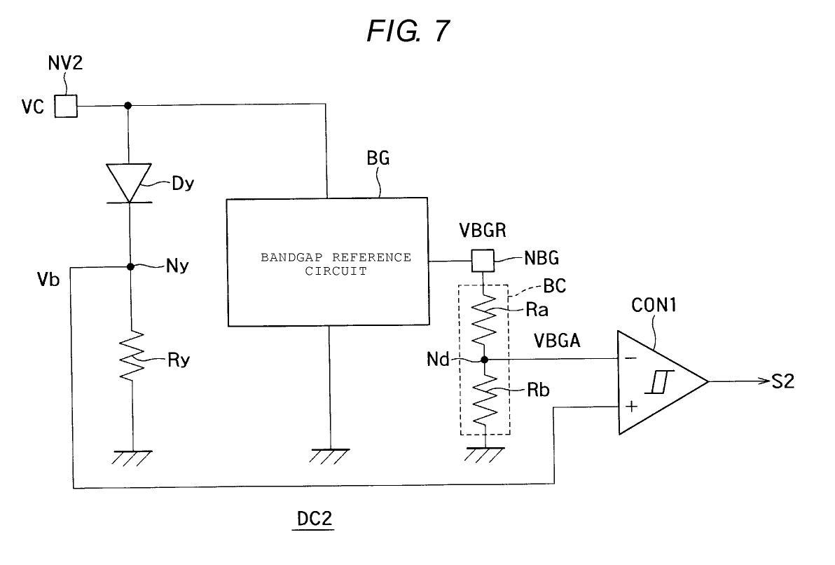

FIG. 7 is a circuit diagram illustrating another example of the circuit configuration of the second voltage detector circuit DC2 of the semiconductor integrated circuit 100 illustrated in FIG. 1. In FIG. 7, reference labels which are the same as the reference labels in FIG. 4 indicate the same configuration as that in the first embodiment.

As illustrated in FIG. 7, the second voltage detector circuit DC2 includes the second detection diode Dy, the second detection resistor Ry, the bandgap reference circuit (reference voltage circuit) BG, the first comparator circuit CON1, and a voltage divider circuit BC.

That is, the second voltage detector circuit DC2 in the second embodiment includes the voltage divider circuit BC as compared with the configuration illustrated in FIG. 4.

The voltage divider circuit BC outputs a divided reference voltage VBGA that is obtained by dividing the reference voltage VBGR. The voltage divider circuit BC, for example, includes a resistor Ra, one terminal of which is connected to the reference node NBG and the other terminal is connected to a node Nd, and a resistor Rb, one terminal of which is connected to the node Nd and the other terminal is grounded, as illustrated in FIG. 7.

The voltage divider circuit BC outputs the divided reference voltage VBGA that is obtained by dividing the reference voltage VBGR using the resistors Ra and Rb.

The first comparator circuit CON1 in the second embodiment compares the divided reference voltage VBGA with the second detected voltage Vb at the second detection node Ny, and outputs the control signal S2 based on the comparison result.

The first comparator circuit CON1, for example, stops outputting the control signal S2 and prevents the activation of the load circuit Y when the second detected voltage Vb is lower than the divided reference voltage VBGA.

Meanwhile, the first comparator circuit CON1 outputs the control signal S2 to permit (enable) the activation of the load circuit Y when the second detected voltage Vb is higher than or equal to the divided reference voltage VBGA.

In general, the values of the reference voltage VBGR and the second detected voltage Vb are determined by the characteristic of semiconductors used to form the various circuit elements. However, the value of the divided reference voltage VBGA can be selected to be an arbitrary value below the value of the reference voltage VBGR.

In the second voltage detector circuit DC2 according to the second embodiment, therefore, a range of the second threshold voltage Vdet2 may be widened by using the divided reference voltage VBGA.

Other configurations of the power supply voltage detector circuit according to the second embodiment are the same as those in the first embodiment. Further, the operation of the power supply voltage detector circuit according to the second embodiment is also the same as that in the first embodiment.

That is, the power supply voltage detector circuit according to the second embodiment, like that in the first embodiment, may be less affected by temperatures even though including elements that have a temperature characteristic.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A power supply voltage detector circuit, comprising:
a switch circuit connected between a first power supply terminal and a first output node that is connectable to a load circuit;
a first voltage detector circuit configured to output a first control signal according to a power supply voltage level at the first power supply terminal, the first control signal controlling the switch circuit to be in a non-conducting state when the power supply voltage level is less than a first threshold voltage level and to be in a conducting state when the power supply voltage level is greater than or equal to the first threshold voltage level; and
a second voltage detector circuit configured to output a second control signal according to an output voltage level at the first output node, the second control signal being output to a second output node that is connectable to the load circuit, wherein
the second control signal disables operation of the load circuit when the output voltage level is less than a second threshold voltage level, which is greater than the first threshold voltage level, and enables operation of the load circuit when the output voltage level is greater than or equal to the second threshold voltage level.

2. The power supply voltage detector circuit according to claim 1, wherein the first voltage detector circuit includes:
a first detection resistor having a first terminal connected to the first power supply terminal,
a first detection diode having a cathode that is grounded and an anode that is connected to a second terminal of the first detection resistor,
a first resistor and a second resistor connected in series, and
a first comparator circuit having a first input terminal connected to a first node between the first and second resistors and a second input terminal connected to the second terminal of the first detection resistor, the first comparator circuit configured to output the first control signal according to a comparison of a voltage at the first node and a voltage at the second terminal of the first detection resistor.

3. The power supply voltage detector circuit according to claim 1, wherein the second voltage detector circuit includes:
a reference voltage circuit configured to output a reference voltage at a reference voltage node according to the output voltage level at the first output node,
a second detection diode having an anode connected to the first output node,
a second detection resistor having a first terminal connected to a cathode of the second detection diode and a second terminal that is grounded, and
a second comparator circuit configured to compare the reference voltage with a second detected voltage, which is at the cathode of the second detection diode, and output the second control signal according to the comparison of the reference voltage and the second detected voltage.

4. The power supply voltage detector circuit according to claim 3, wherein the reference voltage circuit includes:
a driving transistor connected between the first output node and the reference voltage node,
a first resistor having a first terminal connected to the reference voltage node,
a first diode having an anode connected to a second terminal of the first resistor and a cathode that is grounded,
a second resistor having a first terminal connected to the reference voltage node,
a second diode having an anode connected to a second terminal of the second resistor,
a third resistor having a first terminal connected to a cathode of the second diode and a second terminal that is grounded,
a second comparator circuit configured to control a gate voltage of the driving transistor such that a first divided voltage at the second terminal of the first resistor is equal to a second divided voltage at the second terminal of the second resistor, and
a starter circuit configured to control the gate voltage of the driving transistor such that the driving MOS transistor is turned ON while the power supply voltage is lower than or equal to the second threshold voltage level.

5. The power supply voltage detector circuit according to claim 3, wherein, when the second detected voltage is higher than or equal to the reference voltage, the second control signal that is output from the second comparator circuit is at a level that enables the load circuit for operation.

6. The power supply voltage detector circuit according to claim 1, wherein the second voltage detector circuit includes:
a reference voltage circuit configured to output a reference voltage at a reference voltage node according to the output voltage level at the first output node,
a second detection diode having an anode connected to the first output node,
a second detection resistor having a first terminal connected to a cathode of the second detection diode and second terminal that is grounded,
a second voltage divider circuit that outputs a divided reference voltage which is obtained by dividing the reference voltage, and
a second comparator circuit configured to compare the divided reference voltage with a second detected voltage, which is at the cathode of the second detection diode, and output the second control signal according to the comparison of the divided reference voltage and the second detected voltage.

7. The circuit according to claim 6, wherein when the second detected voltage is higher than or equal to the divided reference voltage, the second comparator circuit outputs the second control signal at a level that enables the load circuit operation.

8. The circuit according to claim 6, wherein the reference voltage circuit includes:
a driving transistor connected between the output node and the reference voltage node,
a first resistor having a first terminal connected to the reference voltage node,
a first diode having an anode that is connected to a second terminal of the first resistor and a cathode that is grounded,
a second resistor having a first terminal connected to the reference voltage node,
a second diode having an anode connected to a second terminal of the second resistor,
a third resistor having a first terminal that is connected to a cathode of the second diode and a second terminal that is grounded,
a second comparator circuit configured to control a gate voltage of the driving transistor such that a first divided voltage at the second terminal of the first resistor is equal to a second divided voltage at the second terminal of the second resistor, and
a starter circuit configured to control the gate voltage of the driving transistor such that the driving transistor is turned ON while the power supply voltage is lower than or equal to the second threshold voltage level.

9. The circuit according to claim 8, wherein a resistance value of the first resistor is equal to a resistance value of the second resistor

10. A power supply voltage detector circuit for operating a load circuit comprising:
a power supply terminal, a ground terminal, and a control signal terminal;
a switch circuit having a power supply input, a power supply output, and a control signal input, wherein the power supply input is connected to the power supply terminal;
a first voltage detector circuit having a first input and a first output, wherein the first input is connected to the power supply terminal and the first output is connected to the control signal input of the switch circuit; and
a second voltage detector circuit having a second input and a second output, the second input connected to the power supply output of the switch circuit, wherein
the second voltage detector circuit comprises:
a detection diode having an anode connected to the power supply output of the switch circuit;
a detection resistor connected between the detection diode and the ground terminal;
a first comparator circuit having a first input, a second input, and an output, wherein the second input is connected to a cathode of the detection diode and the output is connected to the control signal terminal; and
a reference circuit having a reference voltage input, a reference voltage output and a driving transistor, the driving transistor having a gate, a source, and a drain, wherein the reference voltage input is connected between the power supply output of the switch circuit and the source of the driving transistor, and the reference voltage output is connected between the drain of the driving transistor and the first input of the first comparator circuit.

11. The power supply voltage detector circuit according to claim 10, wherein the reference circuit further comprises:
a starter circuit having a starting circuit input connected to the reference voltage input of the switch circuit and a starting circuit output connected to the gate of the driving transistor;
a second comparator circuit having a first input, a second input, and an output, wherein the output is connected to the gate;
a first resistor having a first terminal connected to the drain, and a second terminal connected to the first input of the second comparator circuit;
a first diode connected between the second terminal of the first resistor and the ground terminal;
a second resistor having a first terminal connected to the drain, and a second terminal connected to the second input of the second comparator circuit; and
a second diode connected between the second terminal of the second resistor and the ground terminal.

12. The power supply voltage detector circuit according to claim 10, further comprising:
a voltage divider circuit comprising a first dividing resistor and a second dividing resistor, wherein
the first dividing resistor is connected between the reference voltage output and the first input of the first comparator circuit; and
the second dividing resistor is connected between the first dividing resistor and the ground terminal.

13. The power supply voltage detector circuit according to claim 12, wherein the reference circuit further comprises:
a starter circuit having a starting circuit input connected to the reference voltage input of the switch circuit and a starting circuit output connected to the gate of the driving transistor;
a second comparator circuit having a first input, a second input, and an output, wherein the output is connected to the gate;
a first resistor having a first terminal connected to the drain, and a second terminal connected to the first input of the second comparator circuit;
a first diode connected between the second terminal of the first resistor and the ground terminal;
a second resistor having a first terminal connected to the drain, and a second terminal connected to the second input of the second comparator circuit; and
a second diode connected between the second terminal of the second resistor and the ground terminal.

14. A reference voltage generating circuit, comprising:
a driving transistor having a source connected to a power supply terminal and a drain connected to a reference voltage terminal;
a starter circuit having a starting circuit input connected to the power supply terminal and a starting circuit output connected to a gate of the driving transistor;
a comparator circuit having a first input, a second input, and an output connected to the gate of the driving transistor, the comparator circuit configured to output a voltage signal to the output according to a comparison of a voltage level at the first input to a voltage level at the second input;
a first resistor having a first terminal connected to the drain and a second terminal connected to the first input;
a first diode connected between the second terminal of the first resistor and a ground terminal;
a second resistor having a first terminal connected to the drain and a second terminal connected to the second input; and
a second diode connected between the second terminal of the second resistor and the ground terminal.

15. The reference voltage generating circuit according to claim 14, wherein a temperature characteristic of the first diode offsets a temperature characteristic of the second diode.

16. The reference voltage generating circuit according to claim 15, wherein a resistance of the first resistor is substantially equal to a resistance of the second resistor.

17. The reference voltage generating circuit of claim 15, further comprising a third resistor connected between the second resistor and the ground terminal.

18. The reference voltage generating circuit according to claim 14, wherein the comparator circuit further comprises:
a first current source connected to the ground terminal; and
a second current source connected to the ground terminal.

19. The reference voltage generating circuit according to claim 18, wherein the comparator circuit further comprises:
a first n-type transistor having a gate connected to the second terminal of the first resistor and a source connected to the first current source;
a second n-type transistor having a gate connected to the second terminal of the second resistor and a source connected to the first current source;
a first p-type transistor and a second p-type transistor each having a gate connected to a drain of the first n-type transistor, a drain of the first p-type transistor being connected to the drain of the first n-type transistor, and a drain of the second p-type transistor being connected to the drain of the second n-type transistor; and
a third p-type transistor having a gate connected to the drain of the second n-type transistor and a drain connected to the second current source, each p-type transistor having a source connected to the power supply terminal.

20. The reference voltage generating circuit according to claim 14, wherein a junction area of the first diode differs from a junction area of the second diode.
